(19) United States
(12) Patent Application Publication
(10) Pub. No.: US 2024/0385263 A1
(43) Pub. Date: Nov. 21, 2024

(54) MAGNETIZATION ROTATIONAL ELEMENT, MAGNETORESISTANCE EFFECT ELEMENT, AND MAGNETIC MEMORY

(71) Applicant: TDK CORPORATION, Tokyo (JP)

(72) Inventors: Yohei SHIOKAWA, Tokyo (JP); Yugo ISHITANI, Tokyo (JP); Kosuke HAMANAKA, Tokyo (JP)

(73) Assignee: TDK CORPORATION, Tokyo (JP)

(21) Appl. No.: 18/710,841

(22) PCT Filed: Nov. 19, 2021
(86) PCT No.: PCT/JP2021/042576

§ 371 Date: Jul. 29, 2024

(51) Int. Cl. G01R 33/07; H10B 61/00; H10N 52/00

(52) U.S. Cl. CPC G01R 33/075; H10B 61/22; H10N 52/101

(57) ABSTRACT

This magnetization rotational element includes a spin-orbit torque wiring, a first ferromagnetic layer connected to the spin-orbit torque wiring, and a wiring connected to the spin-orbit torque wiring at a position different from that of the first ferromagnetic layer, wherein the spin-orbit torque wiring and the wiring each contain nitrogen, and the spin-orbit torque wiring and the wiring differ from each other in nitrogen content.

### TECHNICAL FIELD

The present disclosure relates to a magnetization rotational element, a magnetoresistance effect element, and a magnetic memory.

### BACKGROUND ART

Giant magnetoresistance (GMR) elements each including a multilayer film of a ferromagnetic layer and a nonmagnetic layer, and tunnel magnetoresistance (TMR) elements each using an insulating layer (a tunnel barrier layer or a barrier layer) as a nonmagnetic layer are known as magnetoresistance effect elements. Magnetoresistance effect elements can be applied to magnetic sensors, high frequency components, magnetic heads, and nonvolatile random access memories (MRAMs).

An MRAM is a memory element in which magnetoresistance effect elements are integrated. An MRAM reads and writes data using the characteristic that a resistance of a magnetoresistance effect element changes when mutual magnetization directions of two ferromagnetic layers between which a nonmagnetic layer is interposed in the magnetoresistance effect element changes. A magnetization direction of a ferromagnetic layer is controlled using, for example, a magnetic field generated by an electric current. For example, a magnetization direction of a ferromagnetic layer is controlled using spin transfer torque (STT) generated by passing an electric current in a laminating direction of a magnetoresistance effect element.

In the case of rewriting the magnetization direction of the ferromagnetic layer using STT, an electric current flows in the laminating direction of the magnetoresistance effect element. A write current is a cause of characteristic deterioration of a magnetoresistance effect element.

In recent years, attention has been focused on a method in which an electric current is not required to flow in a laminating direction of a magnetoresistance effect element at the time of writing (for example, Patent Document 1). One such method is a writing method using a spin-orbit torque (SOT). The SOT is induced by a spin current caused by spin-orbit interaction or by the Rashba effect at an interface between dissimilar materials. An electric current for inducing SOT in a magnetoresistance effect element flows in a direction intersecting a laminating direction of a magnetoresistance effect element. That is, there is no need to flow an electric current in a laminating direction of a magnetoresistance effect element, and it is expected that a life of a magnetoresistance effect element will become longer.

### CITATION LIST

### Patent Document

### Patent Document 1

Japanese Unexamined Patent, First Publication No. 2017-216286

### SUMMARY OF DISCLOSURE

### Technical Problem

A magnetoresistance effect element using SOT writes data by flowing an electric current along a spin-orbit torque wiring. There is a need for a magnetization rotational element, a magnetoresistance effect element, and a magnetic memory that require less electric current to write data and consume less electric power.

The present disclosure has been made in view of the above circumstances, and an object thereof is to provide a magnetization rotational element, a magnetoresistance effect element, and a magnetic memory that can reduce power consumption.

### Solution to Problem

In order to solve the above problems, the present disclosure provides the following means.
(1) A magnetization rotational element according to a first aspect includes a spin-orbit torque wiring, a first ferromagnetic layer, and a wiring. The first ferromagnetic layer is connected to the spin-orbit torque wiring. The wiring is connected to the spin-orbit torque wiring at a position different from that of the first ferromagnetic layer. The spin-orbit torque wiring and the wiring each contain nitrogen. The spin-orbit torque wiring and the wiring differ from each other in nitrogen content.
(2) In the magnetization rotational element according to the above aspect, the wiring may include a first wiring and a second wiring. The first wiring and the second wiring are connected to the spin-orbit torque wiring at positions sandwiching the first ferromagnetic layer when viewed in a laminating direction thereof.
(3) In the magnetization rotational element according to the above aspect, the spin-orbit torque wiring may have a greater nitrogen content than the wiring.
(4) In the magnetization rotational element according to the above aspect, the nitrogen content of the wiring may be 30 atm % or more.
(5) In the magnetization rotational element according to the above aspect, the spin-orbit torque wiring may have a smaller nitrogen content than the wiring.
(6) In the magnetization rotational element according to the above aspect, the nitrogen content of the spin-orbit torque wiring may be 30 atm % or more.
(7) In the magnetization rotational element according to the above aspect, the nitrogen content of the wiring may be 50 at % or less.
(8) In the magnetization rotational element according to the above aspect, a first surface of the spin-orbit torque wiring in contact with the wiring may have a greater nitrogen content than a second surface opposite to the first surface.
(9) In the magnetization rotational element according to the above aspect, the wiring may have a smaller resistivity than the spin-orbit torque wiring.
(10) In the magnetization rotational element according to the above aspect, the spin-orbit torque wiring may include a first metal, the wiring may include a second metal, and the first metal and the second metal may be different from each other. The first metal is one selected from the group consisting of Ti, Cr, Mn, Cu, Mo, Ru, Rh, Hf, Ta, W, Re, Os, Ir, Pt, and Au. The second metal is one selected from the group consisting of Ti, Cr, Cu, Mo, Ru, Ta, and W.
(11) In the magnetization rotational element according to the above aspect, the spin-orbit torque wiring may include a first metal, the wiring may include a second metal, and the first metal and the second metal may be the same.
(12) The magnetization rotational element according to the above aspect may further include a first insulating layer that surrounds a periphery of the spin-orbit torque wiring and contains nitrogen.
(13) The magnetization rotational element according to the above aspect may further include a second insulating layer that surrounds the wiring and contains nitrogen.
(14) The magnetization rotational element according to the above aspect may further include an intermediate layer between the spin-orbit torque wiring and the wiring. The intermediate layer has a greater nitrogen content than the spin-orbit torque wiring and the wiring.
(15) In the magnetization rotational element according to the above aspect, the first ferromagnetic layer may contain nitrogen.
(16) A magnetoresistance effect element according to a second aspect includes the magnetization rotational element according to the above aspect, a second ferromagnetic layer, and a nonmagnetic layer. The nonmagnetic layer is interposed between the first ferromagnetic layer and the second ferromagnetic layer.
(17) A magnetic memory according to a third aspect includes a plurality of the magnetoresistance effect elements according to the above aspect.

### Advantageous Effects of Disclosure

The magnetization rotational element, the magnetoresistance effect element, and the magnetic memory according to the present disclosure can reduce power consumption.

### BRIEF DESCRIPTION OF DRAWINGS

FIG. 1 is a circuit diagram of a magnetic memory according to a first embodiment.

FIG. 2 is a cross-sectional view of a featured portion of the magnetic memory according to the first embodiment.

FIG. 3 is a cross-sectional view of a magnetoresistance effect element according to the first embodiment.

FIG. 4 is a plan view of the magnetoresistance effect element according to the first embodiment.

FIG. 5 is a cross-sectional view of a magnetoresistance effect element according to a first modified example.

FIG. 6 is a cross-sectional view of a magnetoresistance effect element according to a second modified example.

FIG. 7 is a cross-sectional view of a magnetoresistance effect element according to a third modified example.

FIG. 8 is a cross-sectional view of a magnetoresistance effect element according to a fourth modified example.

FIG. 9 is a cross-sectional view of a magnetization rotational element according to a second embodiment.

### DESCRIPTION OF EMBODIMENTS

The present embodiment will be described in detail below with reference to the drawings as appropriate. In the figures used in the following description, in order to make features of the present disclosure easier to understand, featured portions thereof may be shown enlarged for convenience, and dimensional ratios or the like of each constituent element may differ from actual ones. Materials, dimensions, and the like exemplified in the following description are examples, and the present disclosure is not limited thereto and can be implemented with appropriate changes within the scope of achieving the effects of the present disclosure.

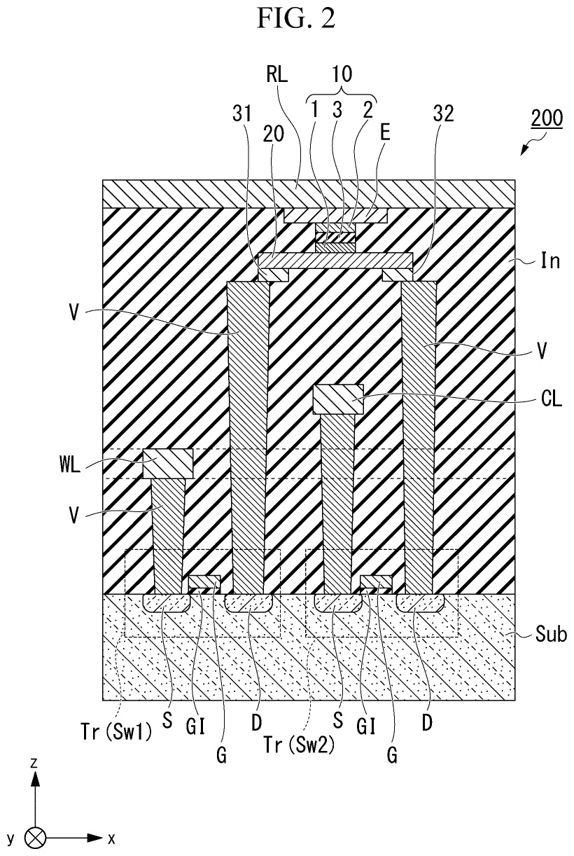

First, directions will be defined. On one surface of a substrate Sub (see FIG. 2), which will be described later, one direction is defined as an x direction, and a direction perpendicular to the x direction is defined as a y direction. The x direction is, for example, a longitudinal direction of a spin-orbit torque wiring 20. A z direction is a direction orthogonal to the x direction and the y direction. The z direction is an example of a laminating direction in which each layer is laminated. Hereinafter, a +z direction may be expressed as “upward” and a-z direction may be expressed as “downward.” Upward and downward do not necessarily correspond to the direction in which gravity is applied.

In the present specification, the expression “extend in the x direction” indicates, for example, that the dimension in the x direction is greater than the smallest dimension among the dimensions in the x direction, the y direction, and the z direction. The same applies to the case of extending in other directions. Further, in the present specification, the term “connection” is not limited to a case of a physical connection. For example, the term “connection” is not limited to a case in which two layers are physically in contact with each other, but also includes a case in which two layers are connected to each other with another layer interposed therebetween. In addition, the term “connection” as used herein includes electrical connection.

### First Embodiment

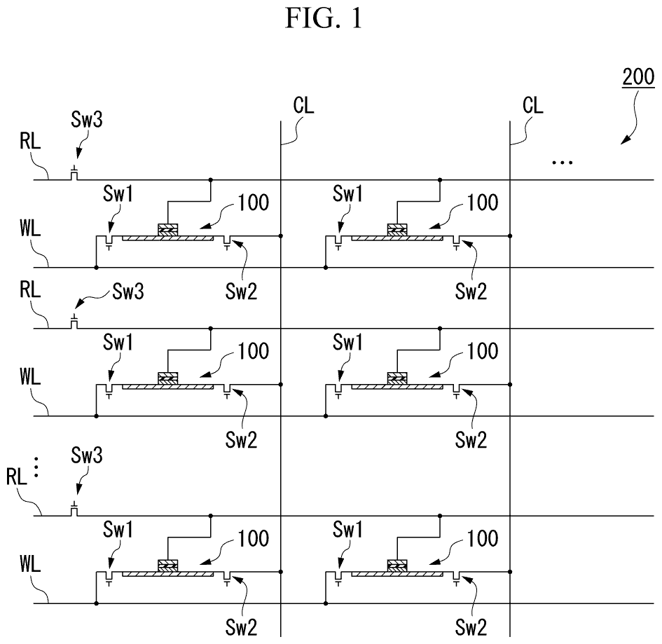

FIG. 1 is a configuration diagram of a magnetic memory 200 according to a first embodiment. The magnetic memory 200 includes a plurality of magnetoresistance effect elements 100, a plurality of write wirings WL, a plurality of common wirings CL, a plurality of read wirings RL, a plurality of first switching elements Sw1, a plurality of second switching elements Sw2, and a plurality of third switching elements Sw3. In the magnetic memory 200, for example, the magnetoresistance effect elements 100 are arranged in an array shape.

Each of the write wirings WL electrically connects a power source to one or more magnetoresistance effect elements 100. Each of the common wirings CL is a wiring used both when writing and reading data. Each of the common wirings CL electrically connects a reference potential to one or more magnetoresistance effect elements 100. The reference potential is, for example, ground. The common wiring CL may be disposed for each of the plurality of magnetoresistance effect elements 100 or may be disposed for the plurality of magnetoresistance effect elements 100. Each of the read wirings RL electrically connects the power source to one or more magnetoresistance effect elements 100. The power source is connected to the magnetic memory 200 in use.

Each of the magnetoresistance effect elements 100 is connected to each of the first switching element Sw1, the second switching element Sw2, and the third switching element Sw3. The first switching element Sw1 is connected between the magnetoresistance effect element 100 and the write wiring WL. The second switching element Sw2 is connected between the magnetoresistance effect element 100 and the common wiring CL. The third switching element Sw3 is connected to the read wiring RL for the plurality of magnetoresistance effect elements 100.

When predetermined first and second switching elements Sw1 and Sw2 are turned on, a write current flows between the write wiring WL and the common wiring CL that are connected to a predetermined magnetoresistance effect element 100. When the write current flows, data is written into the predetermined magnetoresistance effect element 100. When predetermined second and third switching elements Sw2 and Sw3 are turned on, a read current flows between the common wiring CL and the read wiring RL that are connected to a predetermined magnetoresistance effect element 100. When the read current flows, data is read from the predetermined magnetoresistance effect element 100.

The first switching element Sw1, the second switching element Sw2, and the third switching element Sw3 are elements for controlling a flow of an electric current.

The first switching element Sw1, the second switching element Sw2, and the third switching element Sw3 are, for example, transistors, elements that utilize phase changes in crystal layers, such as ovonic threshold switches (OTS), elements that utilize changes in band structure, such as metal-insulator transition (MIT) switches, elements that utilize breakdown voltages, such as Zener diodes and avalanche diodes, or elements whose conductivity changes with changes in atomic positions.

In the magnetic memory 200 shown in FIG. 1, the magnetoresistance effect elements 100 connected to the same read wiring RL share the third switching element Sw3. The third switching element Sw3 may be disposed for each of the magnetoresistance effect elements 100. Also, each of the magnetoresistance effect elements 100 is disposed with the third switching element Sw3, and the first switching element Sw1 or the second switching element Sw2 may be shared by the magnetoresistance effect elements 100 connected to the same wiring.

FIG. 2 is a cross-sectional view of a featured portion of the magnetic memory 200 according to the first embodiment. FIG. 2 is a cross-section of the magnetoresistance effect element 100 along the xz plane passing through a center of a width in the y direction of a spin-orbit torque wiring 20, which will be described later.

The first switching element Sw1 and the second switching element Sw2 shown in FIG. 2 are transistors Tr. The third switching element Sw3 is electrically connected to the read wiring RL and is located at a different position in the x direction in FIG. 2, for example. The transistor Tr is, for example, a field effect transistor and includes a gate electrode G, a gate insulating film GI, and a source S and a drain D formed on a substrate

Sub. The source S and the drain D are defined by a flowing direction of an electric current and are identical regions. A positional relationship between the source S and the drain D may be reversed. The substrate Sub is, for example, a semiconductor substrate.

The transistors Tr and the magnetoresistance effect element 100 are electrically connected to each other via a via wiring V, a first wiring 31, and a second wiring 32. In addition, the transistors Tr and the write wiring WL or the common wiring CL are connected to each other by the via wiring V. For example, the via wiring V extends in the z direction. The read wiring RL is connected to a laminate 10 via an electrode E. The via wiring V and the electrode E include a conductive material. The via wiring V and the first wiring 31 may be integrated. Also, the via wiring V and the second wiring 32 may be integrated. That is, the first wiring 31 may be a part of the via wiring V, and the second wiring 32 may be a part of the via wiring V.

The magnetoresistance effect element 100 and the transistors Tr are surrounded by an insulating layer In. The insulating layer In is an insulating layer that insulates between wirings of multilayer wiring and between elements. The insulating layer In is made of, for example, silicon oxide (SiOₓ), silicon nitride (SiNₓ), silicon carbide (SIC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

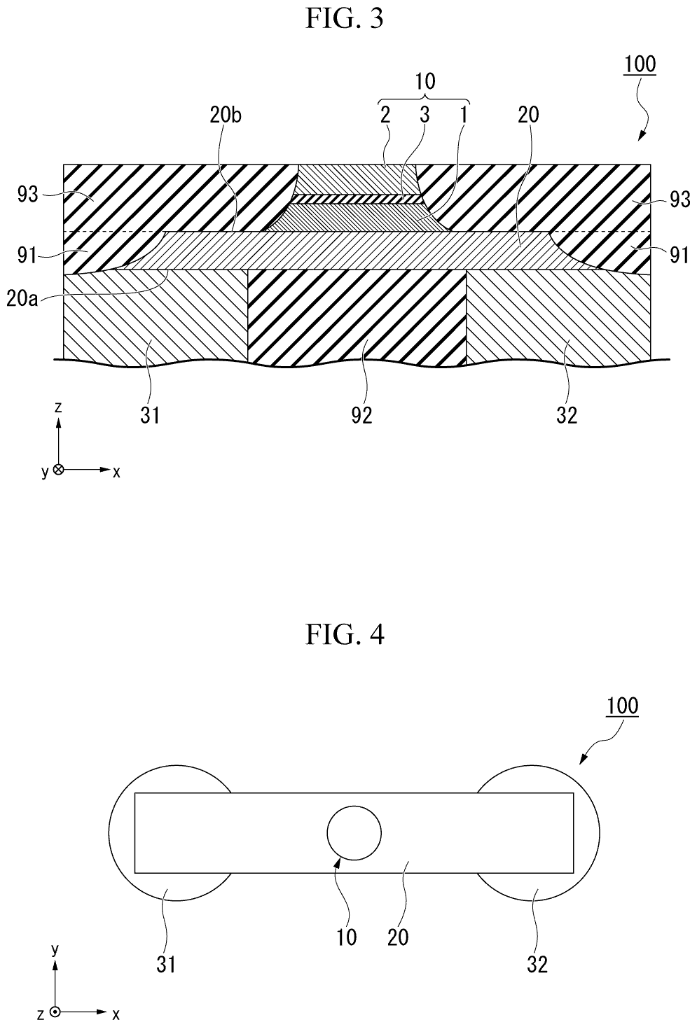

FIG. 3 is a cross-sectional view of the magnetoresistance effect element 100. FIG. 3 is a cross-section of the magnetoresistance effect element 100 along the xz plane passing through the center of the width of the spin-orbit torque wiring 20 in the y direction. FIG. 4 is a plan view of the magnetoresistance effect element 100 in the z direction.

The magnetoresistance effect element 100 includes, for example, the laminate 10, the spin-orbit torque wiring 20, the first wiring 31, and the second wiring 32. The laminate 10 includes a first ferromagnetic layer 1, a second ferromagnetic layer 2, and a nonmagnetic layer 3. A periphery of the magnetoresistance effect element 100 is covered with, for example, a first insulating layer 91, a second insulating layer 92, and a third insulating layer 93. The first insulating layer 91, the second insulating layer 92, and the third insulating layer 93 are part of the above-mentioned insulating layer In.

The magnetoresistance effect element 100 is a magnetic element that uses a spin-orbit torque (SOT), and is sometimes referred to as a spin-orbit torque type magnetoresistance effect element, a spin injection type magnetoresistance effect element, or a spin-current magnetoresistance effect element.

The magnetoresistance effect element 100 is an element for recording and storing data. The magnetoresistance effect element 100 records data using a resistance value of the laminate 10 in the z direction. The resistance value of the laminate 10 in the z direction changes when a write current is applied along the spin-orbit torque wiring 20 and spins are injected into the laminate 10 from the spin-orbit torque wiring 20. The resistance value of the laminate 10 in the z direction can be read when a read current is applied to the laminate 10 in the z direction.

The first wiring 31 and the second wiring 32 are connected to the spin-orbit torque wiring 20 at positions sandwiching the first ferromagnetic layer 1 when viewed in the z direction. Other layers may be disposed between the first wiring 31 and the spin-orbit torque wiring 20 and between the second wiring 32 and the spin-orbit torque wiring 20.

The first wiring 31 and the second wiring 32 are, for example, conductors that electrically connect the switching elements and the magnetoresistance effect element 100. Both the first wiring 31 and the second wiring 32 have conductivity.

The first wiring 31 and the second wiring 32 both contain a metal (hereinafter referred to as a second metal). The second metal is, for example, one selected from the group consisting of Ti, Cr, Cu, Mo, Ru, Ta, and W. The first wiring 31 and the second wiring 32 mainly contain the second metal, for example. The expression “mainly contain” indicates that a proportion of the above metal element contained in the wirings is 50 atm % or more of elements contained in the wirings.

At least one of the first wiring 31 and the second wiring 32 contains nitrogen. Both the first wiring 31 and the second wiring 32 may contain nitrogen. For example, at least one of the first wiring 31 and the second wiring 32 may be a metal nitride of the second metal. The metal nitride is not limited to those in which a metal and nitrogen are combined, but also includes those in which nitrogen has entered a crystal lattice of a metal. When at least one of the first wiring 31 and the second wiring 32 contains nitrogen, nitrogen diffusion from the spin-orbit torque wiring 20 can be inhibited.

For example, the spin-orbit torque wiring 20 has a longer length in the x direction than in the y direction when viewed in the z direction, and extends in the x direction. The write current flows between the first wiring 31 and the second wiring 32 in the x direction along the spin-orbit torque wiring 20. The spin-orbit torque wiring 20 is connected to each of the first wiring 31 and the second wiring 32.

The spin-orbit torque wiring 20 generates a spin current by the spin Hall effect when an electric current flows, and injects spins into the first ferromagnetic layer 1. For example, the spin-orbit torque wiring 20 applies an amount of a spin-orbit torque (SOT) which can reverse magnetization of the first ferromagnetic layer 1 to the magnetization of the first ferromagnetic layer 1. The spin Hall effect is a phenomenon in which, when an electric current flows, a spin current is induced in a direction perpendicular to a flowing direction of the electric current by spin-orbit interaction. The spin Hall effect is similar to a normal Hall effect in that moving (traveling) charges (electrons) can bend a moving (traveling) direction. In the normal Hall effect, a moving direction of charged particles moving in a magnetic field is bent by the Lorentz force. In contrast, in the spin Hall effect, a moving direction of spin is bent simply by movement of electrons (flowing of an electric current) even when there is no magnetic field.

For example, when an electric current flows through the spin-orbit torque wiring 20, a first spin oriented in one direction and a second spin oriented in the opposite direction to the first spin are bent by the spin Hall effect in directions perpendicular to a flowing direction of the electric current. For example, the first spin oriented in a −y direction is bent from the x direction, which is the traveling direction, to the +z direction. The second spin oriented in a +y direction is bent from the x direction, which is the traveling direction, to the −z direction.

In a nonmagnetic material (a material that is not a ferromagnetic material), the number of first spin electrons and the number of second spin electrons produced by the spin Hall effect are equal. That is, the number of first spin electrons oriented in the +z direction is equal to the number of second spin electrons oriented in the −z direction. The first spin and the second spin flow in directions that eliminate an uneven distribution of spins. In movement of the first spin and the second spin in the z direction, flows of the charges cancels each other out, and thus an amount of current becomes zero. A spin current without an electric current is particularly called a pure spin current.

When a flow of first spin electrons is expressed as J_{↑}, a flow of second spin electrons is expressed as J_{↓}, and a spin current is expressed as J_{S}, J_{S} is defined by J_{S}=J_{↑}−J_{↓}. The spin current J_{S} is generated in the z direction. The first spin is injected into the first ferromagnetic layer 1 from the spin-orbit torque wiring 20.

The spin-orbit torque wiring 20 contains, for example, a metal (hereinafter referred to as a first metal). The first metal is, for example, one selected from the group consisting of Ti, Cr, Mn, Cu, Mo, Ru, Rh, Hf, Ta, W, Re, Os, Ir, Pt, and Au. For example, the spin-orbit torque wiring 20 mainly contains the first metal. The expression “mainly contain” indicates that a proportion of the above metal element contained in the spin-orbit torque wiring 20 is 50 atm % or more of elements contained in the spin-orbit torque wiring 20.

The first metal contained in the spin-orbit torque wiring 20 may be the same as or different from the second metal contained in the first wiring 31 or the second wiring 32. When the first metal and the second metal are the same, the cost of procuring materials is reduced. When the first metal and the second metal are different from each other, a type of a metal can be selected depending on a function required for each layer.

The spin-orbit torque wiring 20 contains nitrogen. When the spin-orbit torque wiring 20 contains nitrogen, nitrogen becomes a spin diffusion factor and promotes spin scattering. The spins scattered within the spin-orbit torque wiring 20 are injected into the first ferromagnetic layer 1. That is, when the spin-orbit torque wiring 20 contains nitrogen, spin injection efficiency into the first ferromagnetic layer 1 increases.

The spin-orbit torque wiring 20 may be a metal nitride of the first metal. The metal nitride is not limited to those in which a metal and nitrogen are combined, but also includes those in which nitrogen has entered a crystal lattice of a metal.

A nitrogen content of the spin-orbit torque wiring 20 is different from a nitrogen content of at least one of the first wiring 31 and the second wiring 32. For example, the nitrogen content of the spin-orbit torque wiring 20 is different from the nitrogen content of the first wiring 31 and the nitrogen content of the second wiring 32.

The nitrogen content in each wiring is determined by the following procedure.

The nitrogen content can be measured, for example, by energy dispersive X-ray spectroscopy (EDS) using a transmission electron microscope (TEM), electron energy loss spectroscopy (EELS), or the like. For example, when EDS composition mapping or EELS composition mapping is performed on the spin-orbit torque wiring 20 made into a thin piece of 20 nm or less in the Y direction with an electron beam diameter of 1 nm or less, the nitrogen content of each wiring can be determined. When a thickness of the thin piece is greater than 20 nm, composition information in depth is superimposed, and thus each wiring may be measured not as a layered shape but as a non-uniform distribution. Further, even when the electron beam diameter is greater than 1 nm, energies of adjacent elements are superimposed, and thus each wiring may be measured not as a layered shape but as a non-uniform distribution. Since boundaries between the spin-orbit torque wiring, the first wiring, and the second wiring have finite electron line shapes, a nitrogen distribution may appear continuous.

For example, the nitrogen content of the spin-orbit torque wiring 20 is greater than the nitrogen content of at least one of the first wiring 31 and the second wiring 32. For example, the nitrogen content of the spin-orbit torque wiring 20 is greater than the nitrogen content of the first wiring 31 and the nitrogen content of the second wiring 32. When the nitrogen content of the first wiring 31 and the second wiring 32 is high, resistances of the first wiring 31 and the second wiring 32 become high. When wiring resistances of the first wiring 31 and the second wiring 32 become small, power loss between the magnetoresistance effect elements 100 can be reduced, and power consumption of the magnetic memory 200 can be reduced.

Also, for example, the nitrogen content of the spin-orbit torque wiring 20 may be smaller than the nitrogen content of at least one of the first wiring 31 and the second wiring 32. For example, the nitrogen content of the spin-orbit torque wiring 20 is smaller than the nitrogen content of the first wiring 31 and the nitrogen content of the second wiring 32. In this case, the nitrogen diffusion from the spin-orbit torque wiring 20 to the first wiring 31 or the second wiring 32 can be further inhibited. When an amount of nitrogen contained in the spin-orbit torque wiring 20 is large, the spin injection efficiency into the first ferromagnetic layer 1 is increased, and power consumption of a single magnetoresistance effect element 100 is reduced.

The nitrogen content of the spin-orbit torque wiring 20 is, for example, 30 atm % or more. The nitrogen content of the spin-orbit torque wiring 20 is, for example, 50 atm % or less. The nitrogen content of each of the first wiring 31 and the second wiring 32 is, for example, 30 atm % or more. The nitrogen content of each of the first wiring 31 and the second wiring 32 is, for example, 50 atm % or less.

If the nitrogen content is within the above range, the metal nitride will be stabilized, as can be confirmed in the phase diagram. Also, when the spin-orbit torque wiring 20 contains sufficient nitrogen, spin diffusion efficiency increases. In addition, when the first wiring 31 or the second wiring 32 contains sufficient nitrogen, the nitrogen diffusion from the spin-orbit torque wiring 20 can be inhibited. Further, by not containing too much nitrogen in the first wiring 31 or the second wiring 32, an increase in the wiring resistance can be inhibited.

A resistivity of the spin-orbit torque wiring 20 is, for example, 1 mΩ·cm or more. Also, the resistivity of the spin-orbit torque wiring 20 is, for example, 10 mΩ·cm or less. When the resistivity of the spin-orbit torque wiring 20 is high, a high voltage can be applied to the spin-orbit torque wiring 20. When a potential of the spin-orbit torque wiring 20 becomes high, spins can be efficiently supplied from the spin-orbit torque wiring 20 to the first ferromagnetic layer 1. Further, since the spin-orbit torque wiring 20 has at least a certain level of conductivity, a path of the electric current flowing along the spin-orbit torque wiring 20 can be secured, and the spin current due to the spin Hall effect can be efficiently generated. Resistivities of the first wiring 31 and the second wiring 32 are preferably smaller than the resistivity of the spin-orbit torque wiring 20.

A thickness of the spin-orbit torque wiring 20 is, for example, 4 nm or more. The thickness of the spin-orbit torque wiring 20 may be, for example, 20 nm or less.

The nitrogen content of the spin-orbit torque wiring 20 may be constant within the layer or may vary. For example, a first surface 20a of the spin-orbit torque wiring 20 that is in contact with the first wiring 31 or the second wiring 32 may have a greater nitrogen content than a second surface 20b thereof. The second surface 20b is a surface of the spin-orbit torque wiring 20 that faces the first surface 20a. For example, the nitrogen content of the spin-orbit torque wiring 20 may gradually decrease from the first surface 20a toward the second surface 20b. Since the nitrogen content of the first surface 20a is greater, the nitrogen diffusion from the spin-orbit torque wiring 20 to the first wiring 31 or the second wiring 32 can be further inhibited.

In addition to this, the spin-orbit torque wiring 20 may also contain a magnetic metal or a topological insulator. A topological insulator is a material whose interior is an insulator or a high-resistance material, but whose surface has a spin-polarized metallic state.

The laminate 10 is connected to the spin-orbit torque wiring 20. For example, the laminate 10 is laminated on the spin-orbit torque wiring 20. Other layers may be disposed between the laminate 10 and the spin-orbit torque wiring 20.

The resistance value of the laminate 10 in the z direction changes as spins are injected from the spin-orbit torque wiring 20 into the laminate 10 (first ferromagnetic layer 1).

The laminate 10 is interposed between the spin-orbit torque wiring 20 and the electrode E (see FIG. 2) in the z direction. The laminate 10 is a columnar body. A shape of the laminate 10 when viewed from above in the z direction is, for example, circular, elliptical, or square. For example, side surfaces of the laminate 10 are inclined with respect to the z direction.

The laminate 10 includes, for example, the first ferromagnetic layer 1, the second ferromagnetic layer 2, and the nonmagnetic layer 3. The first ferromagnetic layer 1 is, for example, in contact with the spin-orbit torque wiring 20 and is laminated on the spin-orbit torque wiring 20. Spins are injected into the first ferromagnetic layer 1 from the spin-orbit torque wiring 20. The magnetization of the first ferromagnetic layer 1 is subjected to the spin-orbit torque (SOT) due to the injected spins, and its orientation direction changes. The first ferromagnetic layer 1 and the second ferromagnetic layer 2 interpose the nonmagnetic layer 3 in the z direction.

The first ferromagnetic layer 1 and the second ferromagnetic layer 2 each have magnetization. An orientation direction of the magnetization of the second ferromagnetic layer 2 is less likely to change than that of the first ferromagnetic layer 1 when a predetermined external force is applied. The first ferromagnetic layer 1 is sometimes called a magnetization free layer, and the second ferromagnetic layer 2 is sometimes called a magnetization pinned layer or a magnetization reference layer. The laminate 10 shown in FIG. 3 has the magnetization pinned layer on a side away from the substrate Sub, and is called a top pin structure. The resistance value of the laminate 10 changes depending on a difference in relative angle of magnetization between the first ferromagnetic layer 1 and the second ferromagnetic layer 2 that interpose the nonmagnetic layer 3 therebetween.

The first ferromagnetic layer 1 and the second ferromagnetic layer 2 contain a ferromagnetic material. The ferromagnetic material is, for example, a metal selected from the group consisting of Cr, Mn, Co, Fe, and Ni, an alloy containing one or more of these metals, an alloy containing these metals and at least one element of B, C, and N, or the like. Examples of the ferromagnetic material include Co—Fe, Co—Fe—B, Ni—Fe, a Co—Ho alloy a Sm—Fe alloy, a Fe—Pt alloy, a Co—Pt alloy, and a CoCrPt alloy.

The first ferromagnetic layer 1 and the second ferromagnetic layer 2 may include a Heusler alloy. The Heusler alloy includes an intermetallic compound with a chemical composition of XYZ or X₂YZ. X is Co, Fe, Ni, or a transition metal element or noble metal element of the Cu group on the periodic table, Y is Mn, V, Cr or a transition metal of the Ti group or an elemental species of X, and Z is a typical element from Group III to Group V. Examples of the Heusler alloy include Co₂FeSi, Co₂FeGe, Co₂FeGa, Co₂MnSi, Co₂Mn₁₋ₐFeₐAl_{b}Si_{1-b}, and Co₂FeGe_{1-c}Ga_{c}. The Heusler alloy has a high spin polarizability.

The first ferromagnetic layer 1 may contain nitrogen. When the first ferromagnetic layer 1 contains nitrogen, the nitrogen diffusion from the spin-orbit torque wiring 20 to the first ferromagnetic layer 1 can be inhibited.

The nonmagnetic layer 3 includes a nonmagnetic material. When the nonmagnetic layer 3 is an insulator (a tunnel barrier layer), Al₂O₃, SiO₂, MgO, MgAl₂O₄, and the like can be used for its material. Also, in addition to these materials, materials in which parts of Al, Si, and Mg are replaced with Zn, Be, and the like can also be used. Among these, MgO and MgAl₂O₄ are materials that can realize coherent tunneling, and thus can efficiently inject spins. When the nonmagnetic layer 3 is made of a metal, Cu, Au, Ag, and the like can be used for its material. Further, when the nonmagnetic layer 3 is a semiconductor, Si, Ge, CuInSe₂, CuGaSe₂, Cu(In, Ga)Se₂, and the like can be used for its material.

The laminate 10 may have layers other than the first ferromagnetic layer 1, the second ferromagnetic layer 2, and the nonmagnetic layer 3. For example, an underlayer may be disposed between the spin-orbit torque wiring 20 and the first ferromagnetic layer 1. The underlayer improves crystallinity of each layer constituting the laminate 10. Also, for example, a cap layer may be provided on the uppermost surface of the laminate 10.

Also, in the laminate 10, a ferromagnetic layer may be provided on a surface of the second ferromagnetic layer 2 opposite to the nonmagnetic layer 3 with a spacer layer interposed therebetween. The second ferromagnetic layer 2, the spacer layer, and the ferromagnetic layer have a synthetic antiferromagnetic structure (SAF structure). A synthetic antiferromagnetic structure consists of two magnetic layers between which a nonmagnetic layer is interposed. Antiferromagnetic coupling between the second ferromagnetic layer 2 and the ferromagnetic layer makes a coercive force of the second ferromagnetic layer 2 greater than that in the case without a ferromagnetic layer. The ferromagnetic layer is, for example, IrMn, PtMn, or the like. The spacer layer includes, for example, at least one selected from the group consisting of Ru, Ir, and Rh.

The first insulating layer 91 is on the same level as the spin-orbit torque wiring 20. The first insulating layer 91 extends, for example, in the xy plane. The first insulating layer 91 surrounds the spin-orbit torque wiring 20 when viewed from above in the z direction. For example, the first insulating layer 91 is in contact with the spin-orbit torque wiring 20. For example, the first insulating layer 91 contains nitrogen. When the first insulating layer 91 contains nitrogen, the nitrogen diffusion from the spin-orbit torque wiring 20 can be inhibited. The first insulating layer 91 includes, for example, the same material as the above-described insulating layer In, which is, for example, silicon nitride (SiNx), silicon carbonitride (SiCN), silicon oxynitride (SiON), or aluminum nitride (AlN). Silicon nitride (SiNx) and aluminum nitride (AlN) also have excellent thermal conductivity.

The second insulating layer 92 is on the same level as the first wiring 31 and the second wiring 32. The second insulating layer 92 extends, for example, in the xy plane. The second insulating layer 92 surrounds the first wiring 31 and the second wiring 32 when viewed from above in the z direction. For example, the second insulating layer 92 is in contact with the first wiring 31 and the second wiring 32. For example, the second insulating layer 92 contains nitrogen. For example, the second insulating layer 92 includes the same material as the first insulating layer 91.

The third insulating layer 93 is on the same level as the laminate 10. The third insulating layer 93 extends, for example, in the xy plane. The third insulating layer 93 surrounds a periphery of the laminate 10 when viewed from above in the z direction. For example, the third insulating layer 93 is in contact with the laminate 10. For example, the third insulating layer 93 includes the same material as the first insulating layer 91 or the second insulating layer 92.

Next, a method for manufacturing the magnetoresistance effect element 100 will be described. The magnetoresistance effect element 100 is formed through a process of laminating each layer and a process of processing a part of each layer into a predetermined shape. For the lamination of each layer, a sputtering method, a chemical vapor deposition (CVD) method, an electron beam evaporation method (EB evaporation method), an atomic laser deposition method, or the like can be used. The processing of Each layer can be performed using photolithography or the like.

First, impurities are doped at predetermined positions on the substrate Sub to form the sources S and the drains D. Next, the gate insulating films GI and the gate electrodes G are formed between the sources S and the drains D. The sources S, the drain D, the gate insulating films GI, and the gate electrodes G become the transistors Tr. For the substrate Sub, a commercially available semiconductor circuit board on which the transistors Tr are formed may be used.

Next, the insulating layer In is formed to cover the transistors Tr. Also, by forming opening portions in the insulating layer In and filling the opening portions with a conductor, the via wirings V, the first wiring 31, and the second wiring 32 are formed.

The write wiring WL and the common wiring CL are formed by laminating the insulating layer In to a predetermined thickness, forming grooves in the insulating layer In, and filling the grooves with a conductor.

Next, a layer that will become the spin-orbit torque wiring 20 is formed on one surfaces of the insulating layer In, the first wiring 31, and the second wiring 32. The first wiring 31, the second wiring 32, and the spin-orbit torque wiring 20 contain nitrogen by performing sputtering using a metal nitride target.

Next, a ferromagnetic layer, a nonmagnetic layer, a ferromagnetic layer, and a hard mask layer are laminated in order on the layer that will become the spin-orbit torque wiring 20. Next, the hard mask layer is processed into a predetermined shape. The predetermined shape is, for example, an outer shape of the spin-orbit torque wiring 20. Next, the layer that will become the spin-orbit torque wiring 20, the ferromagnetic layer, the nonmagnetic layer, and the ferromagnetic layer are processed into a predetermined shape at once via the hard mask layer.

Next, unnecessary portions of the hard mask layer in the x direction are removed. The hard mask layer becomes an outer shape of the laminate 10. Next, unnecessary portions of the laminate formed on the spin-orbit torque wiring 20 in the x direction are removed via the hard mask layer. The laminate 10 is processed into a predetermined shape to become the laminate 10. The hard mask layer becomes the electrode E. Next, peripheries of the laminate 10 and the spin-orbit torque wiring 20 are filled with an insulating layer In, and the magnetoresistance effect element 100 is obtained.

The magnetoresistance effect element 100 according to the first embodiment can increase the spin injection efficiency into the first ferromagnetic layer 1 since the spin-orbit torque wiring 20 contains nitrogen. In addition, since at least one of the first wiring 31 and the second wiring 32 contains nitrogen, it is possible to inhibit the nitrogen diffusion from the spin-orbit torque wiring 20 during annealing treatment or the like.

Although an example of the magnetoresistance effect element 100 according to the first embodiment has been shown above, additions, omissions, substitutions, and other changes to the configuration are possible without departing from the spirit of the present disclosure.

### First Modified Example

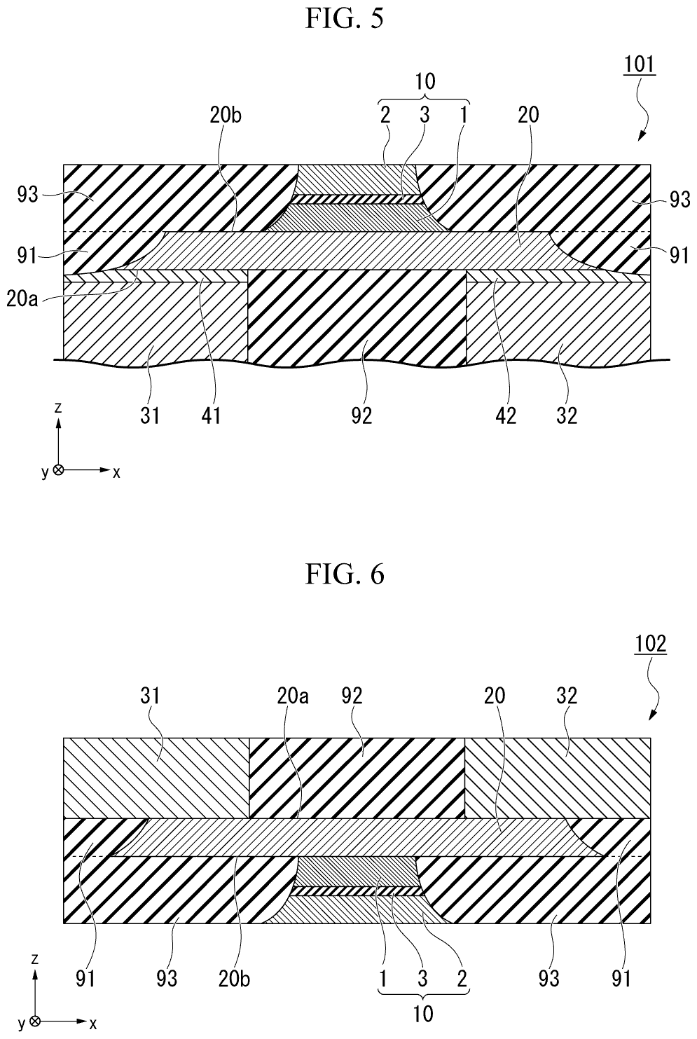

FIG. 5 is a cross-sectional view of a magnetoresistance effect element 101 according to a first modified example. FIG. 5 is a xz cross-section passing through the center of the spin-orbit torque wiring 20 in the y direction. In FIG. 5, the same configurations as those in FIG. 3 will be denoted by the same reference numerals, and explanations thereof will be omitted.

The magnetoresistance effect element 101 according to the first modified example has an intermediate layer 41 between the spin-orbit torque wiring 20 and the first wiring 31, and an intermediate layer 42 between the spin-orbit torque wiring 20 and the second wiring 32.

The intermediate layer 41 and the intermediate layer 42 contain nitrogen. The intermediate layer 41 and the intermediate layer 42 are, for example, metal nitrides. The intermediate layer 41 and the intermediate layer 42 have a greater nitrogen content than the spin-orbit torque wiring 20, the first wiring 31, and the second wiring 32. The intermediate layer 41 inhibits the nitrogen diffusion from the spin-orbit torque wiring 20 to the first wiring 31. The intermediate layer 42 inhibits the nitrogen diffusion from the spin-orbit torque wiring 20 to the second wiring 32.

A thickness of each of the intermediate layer 41 and the intermediate layer 42 is, for example, smaller than or equal to the thickness of the spin-orbit torque wiring 20. When the thicknesses of the intermediate layer 41 and the intermediate layer 42 are thin, current loss in the intermediate layer 41 or the intermediate layer 42 becomes small.

The intermediate layer 41 and the intermediate layer 42 do not need to be completely continuous layers, and may be, for example, a continuous film having a plurality of openings or a layer including a plurality of constituent elements scattered in island shapes.

The magnetoresistance effect element 101 according to the first modified example can achieve the same effects as the magnetoresistance effect element 100 according to the first embodiment.

### Second Modified Example

FIG. 6 is a cross-sectional view of a magnetoresistance effect element 102 according to a second modified example. FIG. 6 is a xz cross-section passing through the center of the spin-orbit torque wiring 20 in the y direction. In FIG. 6, the same configurations as those in FIG. 3 will be denoted by the same reference numerals, and explanations thereof will be omitted.

The laminate 10 shown in FIG. 6 has a bottom pin structure in which the magnetization pinned layer (second ferromagnetic layer 2) is near the substrate Sub. When the magnetization pinned layer is located on the substrate Sub side, stability of magnetization of the magnetization pinned layer increases, and an MR ratio of the magnetoresistance effect element 102 increases. The spin-orbit torque wiring 20 is, for example, on the laminate 10. The first wiring 31 and the second wiring 32 are on the spin-orbit torque wiring 20.

The magnetoresistance effect element 102 according to the second modified example differs only in positional relationships between the respective configurations, and the same effects as those of the magnetoresistance effect element 100 according to the first embodiment can be obtained.

### Third Modified Example

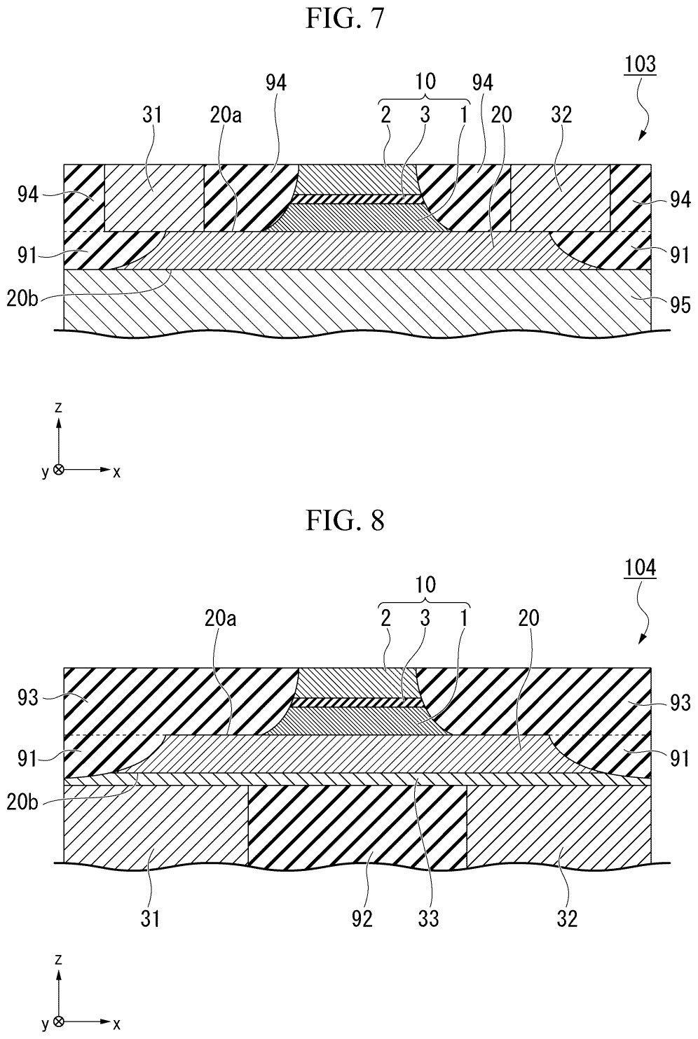

FIG. 7 is a cross-sectional view of a magnetoresistance effect element 103 according to a third modified example. FIG. 7 is a xz cross-section passing through the center of the spin-orbit torque wiring 20 in the y direction. In FIG. 7, the same configurations as those in FIG. 3 will be denoted by the same reference numerals, and explanations thereof will be omitted.

In the magnetoresistance effect element 103 shown in FIG. 7, the laminate 10 is laminated on the first surface 20a of the spin-orbit torque wiring 20 to which the first wiring 31 is connected. That is, the laminate 10, the first wiring 31, and the second wiring 32 are connected to the same surface (first surface 20a) of the spin-orbit torque wiring 20.

The magnetoresistance effect element 103 according to the third modified example differs only in positional relationships between the respective configurations, and the same effects as those of the magnetoresistance effect element 100 according to the first embodiment can be obtained.

### Fourth Modified Example

FIG. 8 is a cross-sectional view of a magnetoresistance effect element 104 according to a fourth modified example. FIG. 8 is a xz cross-section passing through the center of the spin-orbit torque wiring 20 in the y direction. In FIG. 8, the same configurations as those in FIG. 3 will be denoted by the same reference numerals, and explanations thereof will be omitted.

The magnetoresistance effect element 104 shown in FIG. 8 further includes a third wiring 33. The third wiring 33 extends along the spin-orbit torque wiring 20. The third wiring 33 is in contact with the spin-orbit torque wiring 20.

The third wiring 33 contains nitrogen. A nitrogen content of the third wiring 33 is different from the nitrogen content of the spin-orbit torque wiring 20. The nitrogen content of the third wiring 33 may be greater or smaller than the nitrogen content of the spin-orbit torque wiring.

The third wiring 33 includes a metal. The metal included in the third wiring 33 is the same as the second metal. The third wiring 33 mainly contains the second metal, for example. The third wiring 33 may be, for example, a metal nitride of the second metal.

In the fourth modified example, the first wiring 31 and the second wiring 32 do not necessarily need to contain nitrogen.

The magnetoresistance effect element 104 according to the fourth modified example can achieve the same effects as the magnetoresistance effect element 100 according to the first embodiment.

### Second Embodiment

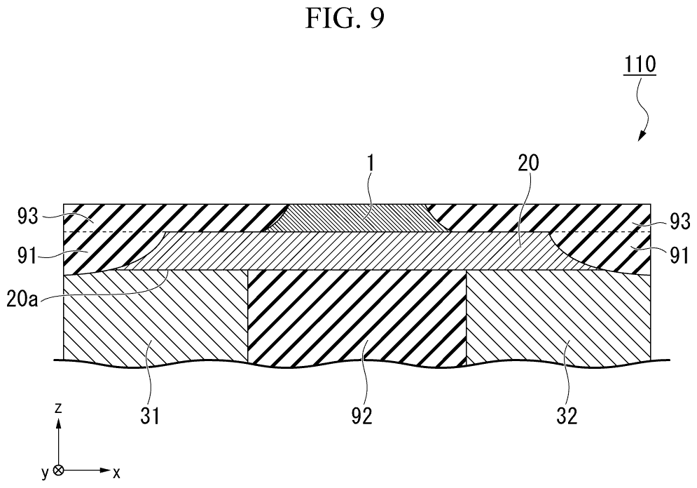

FIG. 9 is a cross-sectional view of a magnetization rotational element 110 according to a second embodiment. In FIG. 9, the magnetization rotational element 110 is replaced with the magnetoresistance effect element 100 according to the first embodiment.

For example, the magnetization rotational element 110 makes light incident on the first ferromagnetic layer 1 and evaluates the light reflected by the first ferromagnetic layer 1. When an orientation direction of magnetization changes due to the magnetic Kerr effect, a polarization state of the reflected light changes. The magnetization rotational element 110 can be used, for example, as an optical element such as an image display device that utilizes a difference in polarization state of light.

In addition, the magnetization rotational element 110 can be used alone as an anisotropic magnetic sensor, an optical element using the magnetic Faraday effect, or the like.

The spin-orbit torque wiring 20, the first wiring 31, and the second wiring 32 of the magnetization rotational element 110 contain nitrogen.

In the magnetization rotational element 110 according to the second embodiment, only the nonmagnetic layer 3 and the second ferromagnetic layer 2 are removed from the magnetoresistance effect element 100, and the same effects as the magnetoresistance effect element 100 according to the first embodiment can be obtained.

Although the preferred aspects of the present disclosure have been illustrated above on the basis of the first embodiment, the second embodiment, and the modified examples, but the present disclosure is not limited to these embodiments. For example, featured configurations of each of the embodiments and the modified examples may be applied to other embodiments and modified examples.

### REFERENCE SIGNS LIST

1 First ferromagnetic layer
2 Second ferromagnetic layer
3 Nonmagnetic layer
10 Laminate
20 Spin-orbit torque wiring
31 First wiring
32 Second wiring
41, 42 Intermediate layer
91 First insulating layer
92 Second insulating layer
93 Third insulating layer
100, 101, 102, 103, 104 Magnetoresistance effect element
110 Magnetization rotational element
200 Magnetic memory
CL Common wiring
RL Read wiring
WL Write wiring
In Insulating layer

1. A magnetization rotational element comprising:
a spin-orbit torque wiring;
a first ferromagnetic layer connected to the spin-orbit torque wiring; and
a wiring connected to the spin-orbit torque wiring at a connection position different from that to which the first ferromagnetic layer is connected,
wherein the spin-orbit torque wiring and the wiring each contain nitrogen, and
the spin-orbit torque wiring and the wiring differ from each other in nitrogen content.

2. The magnetization rotational element according to claim 1,
wherein the wiring includes a first wiring and a second wiring, and
the first wiring and the second wiring are connected to the spin-orbit torque wiring at positions sandwiching the first ferromagnetic layer when viewed in a laminating direction thereof.

3. The magnetization rotational element according to claim 1, wherein the spin-orbit torque wiring has a greater nitrogen content than the wiring.

4. The magnetization rotational element according to claim 3, wherein the nitrogen content of the wiring is 30 atm % or more.

5. The magnetization rotational element according to claim 1, wherein the spin-orbit torque wiring has a smaller nitrogen content than the wiring.

6. The magnetization rotational element according to claim 5, wherein the nitrogen content of the spin-orbit torque wiring is 30 atm % or more.

7. The magnetization rotational element according to claim 1, wherein the nitrogen content of the wiring is 50 at % or less.

8. The magnetization rotational element according to claim 1, wherein a first surface of the spin-orbit torque wiring in contact with the wiring has a greater nitrogen content than a second surface opposite to the first surface.

9. The magnetization rotational element according to claim 1, wherein the wiring has a smaller resistivity than the spin-orbit torque wiring.

10. The magnetization rotational element according to claim 1,
wherein the spin-orbit torque wiring includes a first metal,
the wiring includes a second metal,
the first metal and the second metal are different from each other,
the first metal is one selected from the group consisting of Ti, Cr, Mn, Cu, Mo, Ru, Rh, Hf, Ta, W, Re, Os, Ir, Pt, and Au, and
the second metal is one selected from the group consisting of Ti, Cr, Cu, Mo, Ru, Ta, and W.

11. The magnetization rotational element according to claim 1,
wherein the spin-orbit torque wiring includes a first metal,
the wiring includes a second metal, and
the first metal and the second metal are the same.

12. The magnetization rotational element according to claim 1 further comprising a first insulating layer that surrounds a periphery of the spin-orbit torque wiring,
wherein the first insulating layer contains nitrogen.

13. The magnetization rotational element according to claim 1 further comprising a second insulating layer that surrounds the wiring,
wherein the second insulating layer contains nitrogen.

14. The magnetization rotational element according to claim 1 further comprising an intermediate layer between the spin-orbit torque wiring and the wiring,
wherein the intermediate layer has a greater nitrogen content than the spin-orbit torque wiring and the wiring.

15. The magnetization rotational element according to claim 1, wherein the first ferromagnetic layer contains nitrogen.

16. A magnetoresistance effect element comprising:
the magnetization rotational element according to claim 1,
a second ferromagnetic layer, and
a nonmagnetic layer,
wherein the nonmagnetic layer is interposed between the first ferromagnetic layer and the second ferromagnetic layer.

17. A magnetic memory comprising a plurality of the magnetoresistance effect elements according to claim 16.
